(19) United States
(12) Patent Application Publication
(10) Pub. No.: US 2023/0083432 A1
(43) Pub. Date: Mar. 16, 2023

(54) BURIED POWER RAIL FOR SEMICONDUCTORS

(71) Applicant: INTERNATIONAL BUSINESS MACHINES CORPORATION, Armonk, NY (US)

(72) Inventors: Kangguo Cheng, Schenectady, NY (US); Julien Frougier, Albany, NY (US); Ruilong Xie, Niskayuna, NY (US); Chanro Park, Clifton Park, NY (US)

(21) Appl. No.: 17/474,271

(22) Filed: Sep. 14, 2021

(51) Int. Cl. H01L 21/74; H01L 21/762; H01L 23/535

(52) U.S. Cl. CPC H01L 21/743; H01L 21/76283; H01L 23/535; H01L 29/41791

(57) ABSTRACT

A semiconductor structure includes a field effect transistor (FET) having a source/drain, a contact in contact with the source/drain, and a buried power rail including a conductive material, wherein the buried power rail is in contact with the contact, wherein a first portion of the buried power rail closest to the contact has a first thickness, and wherein a second portion of the buried power rail has a second thickness such that the first thickness is less than the second thickness.

### BACKGROUND

The present invention relates generally to semiconductor devices, and more specifically, to forming a semiconductor device with a buried power rail.

Semiconductor devices are used in a variety of electronic applications, such as personal computers, cell phones, digital cameras, and other electronic equipment. Semiconductor devices are usually fabricated by sequentially depositing insulating or dielectric layers, conductive layers, and semiconductive layers of material over a semiconductor substrate, and patterning the various material layers using lithography to form circuit components and elements thereon. The semiconductor industry has experienced rapid growth due to improvements in the integration density of a variety of electronic components (e.g., transistors, diodes, resistors, capacitors, etc.). For the most part, this improvement in integration density has come from shrinking the semiconductor process node. With the increased demands for miniaturization, higher speed, greater bandwidth, lower power consumption, and lower latency, chip layout has become more complicated and difficult to achieve in the production of semiconductor dies.

### SUMMARY

In accordance with an embodiment, a semiconductor structure is provided. The semiconductor structure includes a field effect transistor (FET) having a source/drain, a contact in contact with the source/drain, and a buried power rail including a conductive material, wherein the buried power rail is in contact with the contact, wherein a first portion of the buried power rail closest to the contact has a first thickness, and wherein a second portion of the buried power rail has a second thickness such that the first thickness is less than the second thickness.

In accordance with another embodiment, a method is provided for forming a semiconductor device with a buried power rail. The method includes forming a plurality of fins over a substrate, depositing a first conformal dielectric over the plurality of fins, depositing a second conformal dielectric over the first conformal dielectric to pinch off fins of the plurality of fins with a tight pitch while leaving spacing between fin arrays, recessing the substrate to form trenches for the buried power rail (BPR), epitaxially growing a sacrificial material in the trenches, forming shallow trench isolation (STI) regions over the sacrificial material, forming front-end-of-the-line (FEOL), middle-of-the-line (MOL), and back-end-of-the-line (BEOL) structures to define a wafer structure having at least a MOL power rail contact, flipping the wafer structure, mounting the wafer structure to a wafer carrier, selectively removing the sacrificial material, forming sidewall spacers, patterning the MOL power rail contact, and forming metallization representing the BPR to the MOL power rail contact.

In accordance with yet another embodiment, a method is provided for forming a semiconductor device with a buried power rail. The method includes forming a plurality of fins over a substrate, epitaxially growing sacrificial silicon germanium (SiGe) within the substrate, forming front-end-of-the-line (FEOL), middle-of-the-line (MOL), and back-end-of-the-line (BEOL) structures to define a wafer structure having at least a MOL power rail contact, flipping the wafer structure, removing the sacrificial SiGe to form trenches, and filling at least one of the trenches with a conductive material representing the BPR to the MOL power rail contact.

It should be noted that the exemplary embodiments are described with reference to different subject-matters. In particular, some embodiments are described with reference to method type claims whereas other embodiments have been described with reference to apparatus type claims. However, a person skilled in the art will gather from the above and the following description that, unless otherwise notified, in addition to any combination of features belonging to one type of subject-matter, also any combination between features relating to different subject-matters, in particular, between features of the method type claims, and features of the apparatus type claims, is considered as to be described within this document.

These and other features and advantages will become apparent from the following detailed description of illustrative embodiments thereof, which is to be read in connection with the accompanying drawings.

### BRIEF DESCRIPTION OF THE DRAWINGS

The invention will provide details in the following description of preferred embodiments with reference to the following figures wherein:

FIG. 1 is a cross-sectional view of a semiconductor structure including a plurality of fins over a semiconductor substrate, in accordance with an embodiment of the present invention;

FIG. 2 is a cross-sectional view of the semiconductor structure of FIG. 1 where a first conformal dielectric is deposited over the plurality of fins, in accordance with an embodiment of the present invention;

FIG. 3 is a cross-sectional view of the semiconductor structure of FIG. 2 where a second conformal dielectric is deposited over the first conformal dielectric to pinch off fins with a tight pitch, in accordance with an embodiment of the present invention;

FIG. 4 is a cross-sectional view of the semiconductor structure of FIG. 3 where a reactive ion etch (RIE) takes place to form trenches for the buried power rail, in accordance with an embodiment of the present invention;

FIG. 5 is a cross-sectional view of the semiconductor structure of FIG. 4 where epitaxial growth is deposited in the trenches, in accordance with an embodiment of the present invention;

FIG. 6 is a cross-sectional view of the semiconductor structure of FIG. 5 where shallow trench isolation (STI) regions are formed, in accordance with an embodiment of the present invention;

FIG. 7 is a cross-sectional view and top-down view of the semiconductor structure of FIG. 6 where the hardmask is removed, a dummy gate is formed, gate spacers are formed, and source/drain epitaxy is deposited over the recessed fins, in accordance with an embodiment of the present invention;

FIG. 8 is a cross-sectional view of the semiconductor structure of FIG. 7 where middle-of-the line (MOL) and back-end-of-the-line (BEOL) formation is completed, in accordance with an embodiment of the present invention;

FIG. 9 is a cross-sectional view of the semiconductor structure of FIG. 8 where the wafer is flipped and mounted to a wafer carrier or another wafer to expose the epitaxial growth, in accordance with an embodiment of the present invention;

FIG. 10 is a cross-sectional view of the semiconductor structure of FIG. 9 where the epitaxial growth is selectively removed, in accordance with an embodiment of the present invention;

FIG. 11 is a cross-sectional view of the semiconductor structure of FIG. 10 where dielectric spacers are formed adjacent trench sidewalls, in accordance with an embodiment of the present invention;

FIG. 12 is a cross-sectional view of the semiconductor structure of FIG. 11 where a low-k dielectric is deposited and planarized, in accordance with an embodiment of the present invention;

FIG. 13 is a cross-sectional view of the semiconductor structure of FIG. 12 where a mask is applied and an opening is created to the power rail contact, in accordance with an embodiment of the present invention;

FIG. 14 is a cross-sectional view of the semiconductor structure of FIG. 13 where the mask is removed and a metal fill takes place to create the buried power rail, in accordance with an embodiment of the present invention; and

FIG. 15 is a cross-sectional view of the semiconductor structure of FIG. 14 where a power supply is formed on the backside of the wafer, in accordance with an embodiment of the present invention.

Throughout the drawings, same or similar reference numerals represent the same or similar elements.

### DETAILED DESCRIPTION

Embodiments in accordance with the present invention provide methods and devices for forming improved buried power rails. The buried power rail (BPR) has been pursued as a viable design-technology co-optimization (DTCO) knob for reducing standard cell size. However, conventional BPR structures exhibit certain issues such as potential metal contamination, as BPR metal is formed in the early stage of device fabrication (fin or nanosheet module), and BPR variation, due to BPR metal recess variation. The exemplary embodiments of the present invention alleviate such issues by providing a method and structure for forming a BPR by using self-aligned silicon germanium (SiGe) epitaxy as a sacrificial placeholder for the BPR. The exemplary embodiments eliminate the metal contamination issue as SiGe is fully compatible with front-end-of-the-line (FEOL) processes and precise controlling of the BPR height is achievable as SiGe epitaxy is selective and self-aligned. Thus, sacrificial SiGe can be employed to create BPR fully compatible with FEOL device fabrication.

Examples of semiconductor materials that can be employed in forming such structures include silicon (Si), germanium (Ge), silicon germanium alloys (SiGe), carbon doped silicon (Si:C), carbon doped silicon germanium carbide (SiGe:C), III-V compound semiconductors and/or II-VI compound semiconductors. III-V compound semiconductors are materials that include at least one element from Group III of the Periodic Table of Elements and at least one element from Group V of the Periodic Table of Elements. II-VI compound semiconductors are materials that include at least one element from Group II of the Periodic Table of Elements and at least one element from Group VI of the Periodic Table of Elements.

It is to be understood that the present invention will be described in terms of a given illustrative architecture; however, other architectures, structures, substrate materials and process features and steps/blocks can be varied within the scope of the present invention. It should be noted that certain features cannot be shown in all figures for the sake of clarity. This is not intended to be interpreted as a limitation of any particular embodiment, or illustration, or scope of the claims.

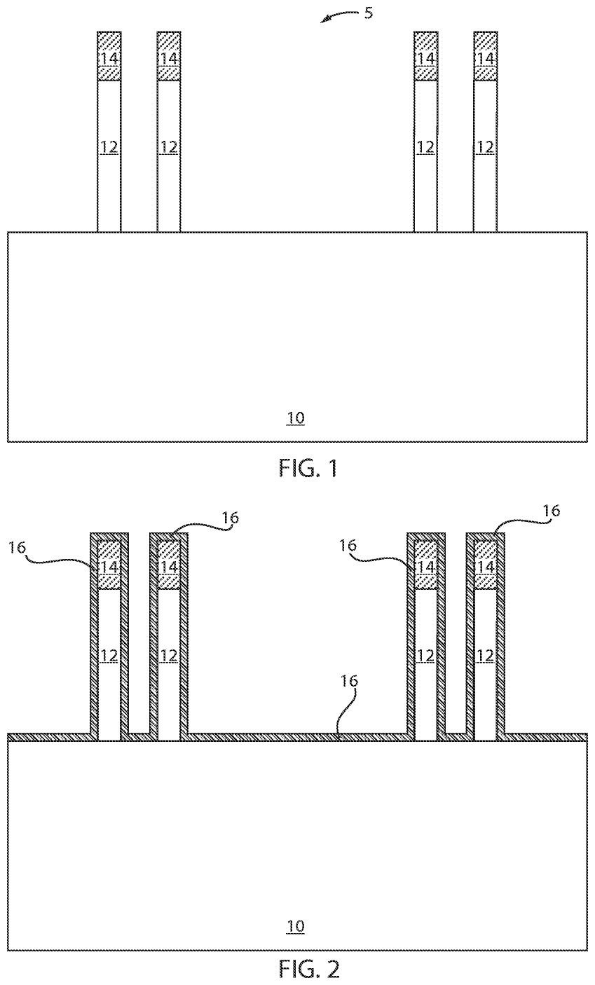

FIG. 1 is a cross-sectional view of a semiconductor structure including a plurality of fins over a semiconductor substrate, in accordance with an embodiment of the present invention.

In structure 5, a plurality of fins 12 are formed over a substrate 10. A hardmask 14 is formed over the plurality of fins 12.

The substrate 10 can be crystalline, semi-crystalline, microcrystalline, or amorphous. The substrate 10 can be essentially (e.g., except for contaminants) a single element (e.g., silicon), primarily (e.g., with doping) of a single element, for example, silicon (Si) or germanium (Ge), or the substrate 10 can include a compound, for example, Al₂O₃, SiO₂, GaAs, SiC, or SiGe. The substrate 10 can also have multiple material layers. In some embodiments, the substrate 10 includes a semiconductor material including, but not necessarily limited to, silicon (Si), silicon germanium (SiGe), Si:C (carbon doped silicon), carbon doped silicon germanium (SiGe:C), carbon doped silicon germanium (SiGe:C), III-V (e.g., GaAs, AlGaAs, InAs, InP, etc.), II-V compound semiconductor (e.g., ZnSe, ZnTe, ZnCdSe, etc.) or other like semiconductor. In addition, multiple layers of the semiconductor materials can be used as the semiconductor material of the substrate 10. In some embodiments, the substrate 10 includes both semiconductor materials and dielectric materials.

The plurality of fins 12 with a hardmask 14 can be formed from a semiconductor material including, but not limited to Si, strained Si, Si:C, SiGe, SiGe:C, Si alloys, Ge, Ge alloys, GaAs, InAs, InP, as well as other III/V and II/VI compound semiconductors. The plurality of fins 12 can be etched by employing, e.g., a reactive ion etch (RIE) or the like. In other embodiments, the etching can include a dry etching process such as, for example, reactive ion etching, plasma etching, ion etching or laser ablation. The etching can further include a wet chemical etching process in which one or more chemical etchants are employed to remove portions of the layers.

It is further noted that fins 12 can have different spacings between them. The leftmost fins can be spaced together (having a first pitch) and a gap can be formed between them and the rightmost fins which are spaced together (having a second pitch). Thus, the first set of fins (leftmost) have a first pitch therebetween and the second set of fins (rightmost) have a second pitch therebetween. A third pitch can be defined between a fin in the first set of fins (leftmost) and a fin in the second set of fins (rightmost). The third pitch would be greater than the first and second pitches.

The hardmask 14 can be manufactured of silicon nitride (SiN), deposited using, for example, chemical vapor deposition (CVD). In other example embodiments, the hardmask 14 can include, but is not limited to, hafnium oxide (HfO₂) or tantalum nitride (TaN) or titanium nitride (TiN). In some embodiments, the hardmask 14 can include multiple layers, for example, silicon nitride on top of silicon oxide. The hardmask 14 can be patterned by any suitable patterning technique, including but not limited to, sidewall image transfer (SIT), self-aligned double patterning (SADP), self-aligned quadruple patterning (SAQP), lithography followed by etching, etc.

FIG. 2 is a cross-sectional view of the semiconductor structure of FIG. 1 where a first conformal dielectric is deposited over the plurality of fins, in accordance with an embodiment of the present invention.

A first conformal dielectric 16 is deposited over the plurality of fins 12 with the hardmask 14. In one example, the first conformal dielectric 16 can be, e.g., SiN.

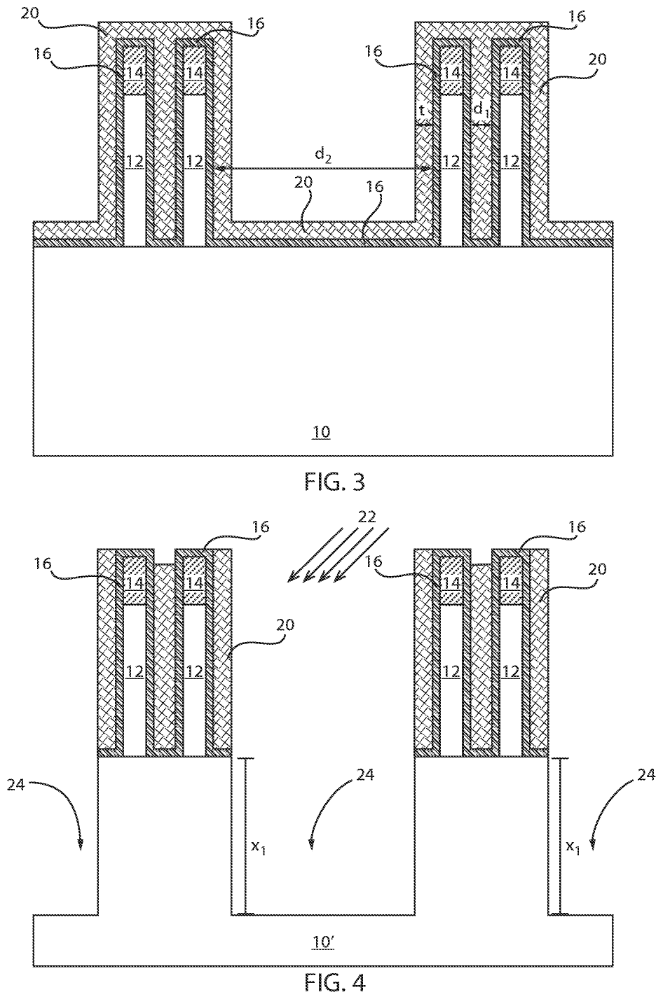

FIG. 3 is a cross-sectional view of the semiconductor structure of FIG. 2 where a second conformal dielectric is deposited over the first conformal dielectric to pinch off fins with a tight pitch, in accordance with an embodiment of the present invention.

A second conformal dielectric 20 is deposited over the first conformal dielectric 16. The second conformal dielectric 20 can be, e.g., an oxide. The second conformal dielectric 20 can pinch off fins 12 with a tight pitch while leaving spacing between fin arrays. The thickness (t) of the oxide 20 is equal to or greater than half of narrow spacing (d₁) within fin array and less than half of the spacing (d₂) between the fin arrays, i.e., ½ d₁<t<½ d₂.

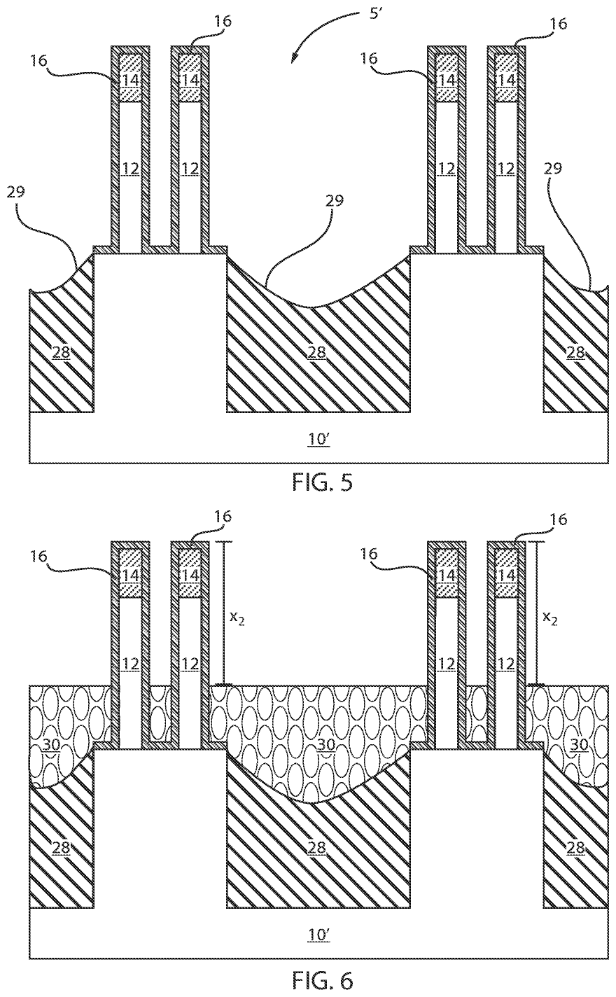

FIG. 4 is a cross-sectional view of the semiconductor structure of FIG. 3 where a reactive ion etch (RIE) takes place to form trenches for the buried power rail, in accordance with an embodiment of the present invention.

A reactive ion etch (RIE) 22 takes place to etch the substrate 10 to form trenches 24 for the buried power rail (BPR). Substrate 10 can be etched by a distance x₁. The remaining substrate can be designated as 10′. The plurality of fins 12, the first conformal dielectric 16, and the second conformal dielectric 20 remain intact.

FIG. 5 is a cross-sectional view of the semiconductor structure of FIG. 4 where epitaxial growth is deposited in the trenches, in accordance with an embodiment of the present invention.

In structure 5′, an epitaxial growth 28 is formed within the trenches 24. The top surface 29 of the epitaxial growths 28 can be, e.g., curved or non-linear or concave. In one example, the epitaxial growth 28 can be, e.g., SiGe. The epitaxial growth 28 acts as a placeholder for the buried power rail. Thus, the epitaxial growth 28 acts as a sacrificial material to be replaced by the BPR.

The advantages of using a sacrificial material such as SiGe is that SiGe is fully compatible with the front-end-of-the-line (FEOL) process. Therefore, there is no potential metal contamination issue present. Moreover, the buried power rail depth is well controlled by self-aligned SiGe epitaxy. No metal recess is needed, and, thus, metal recess depth variation is avoided. Further, thanks to the selective epitaxy, the sacrificial SiGe grows only on exposed semiconductor surfaces and not on the dielectric liner 16. Structurally, the top corners of the sacrificial SiGe are substantially at the same level as the bottom of the dielectric liner 16 (and the bottom of the fins). Later on when the BPR is formed in place of the sacrificial SiGe, the BPR follows the profile of the sacrificial SiGe and allows the precise placement of BPR relative to fin bottom.

Further, the second conformal dielectric 20 is removed before or after deposition of the epitaxial growth 28, thus exposing the first conformal dielectric 16. However, the first conformal dielectric 16 is sufficient to protect the plurality of fins 12 during epitaxy.

The terms “epitaxial growth” and “epitaxial deposition” refer to the growth of a semiconductor material on a deposition surface of a semiconductor material, in which the semiconductor material being grown has substantially the same crystalline characteristics as the semiconductor material of the deposition surface. The term “epitaxial material” denotes a material that is formed using epitaxial growth. In some embodiments, when the chemical reactants are controlled and the system parameters set correctly, the depositing atoms arrive at the deposition surface with sufficient energy to move around on the surface and orient themselves to the crystal arrangement of the atoms of the deposition surface. Thus, in some examples, an epitaxial film deposited on a {100} crystal surface will take on a {100} orientation.

FIG. 6 is a cross-sectional view of the semiconductor structure of FIG. 5 where shallow trench isolation (STI) regions are formed, in accordance with an embodiment of the present invention.

An STI region 30 is deposited over the epitaxial growth 28. The STI region 30 is recessed such that a top portion of the plurality of fins 12 with the hardmask 14 remains exposed. In one example, a portion extending a distance x₂ remains exposed. Thus, the STI regions 30 do not entirely cover or surround the fins 12. In one example, STI regions 30 can include oxide (STI oxide).

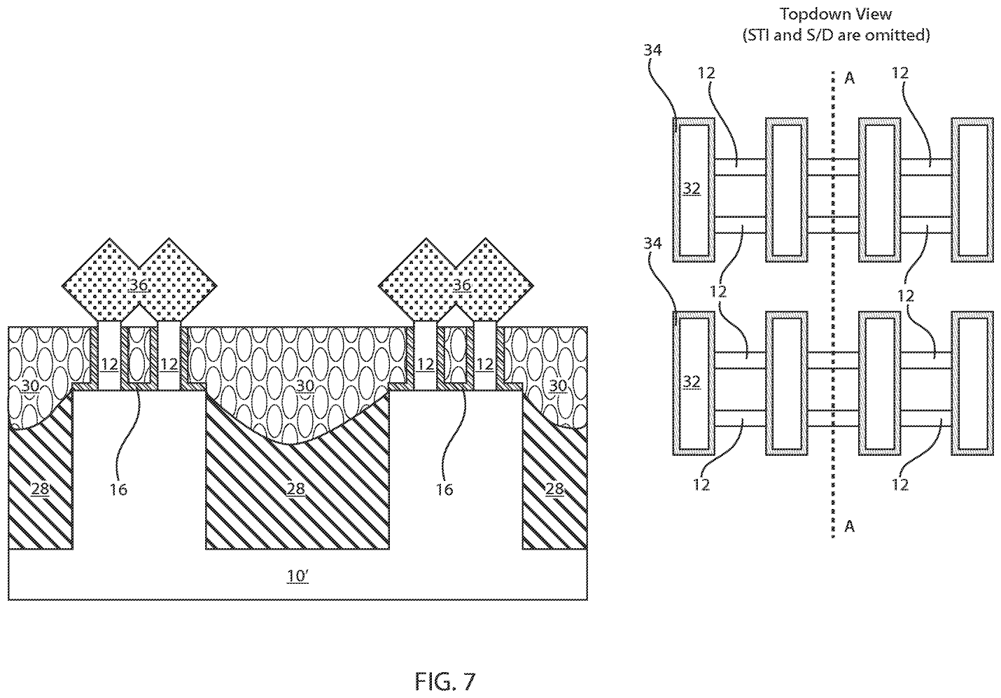

FIG. 7 is a cross-sectional view and top-down view of the semiconductor structure of FIG. 6 where the hardmask 14 is removed, a dummy gate 32 is formed, gate spacers 34 are formed, and source/drain epitaxy 36 is deposited over the recessed fins, in accordance with an embodiment of the present invention.

In some embodiments, the plurality of fins 12 are recessed and hardmask 14 is removed before source/drain epitaxy 36 is formed. In other embodiments, fins recess can be skipped.

Dummy gates 32 are formed and then gate spacers 34 are formed adjacent the dummy gates 32, as shown in the top down view of FIG. 7. Subsequently, source/drain epitaxy or source/drain epi regions 36 are formed over the plurality of fins 12. The source/drain epi regions 36 directly contact an entire upper surface of the fins 12.

It is to be understood that the term “source/drain region” as used herein means that a given source/drain region can be either a source region or a drain region, depending on the application.

Examples of various epitaxial growth processes include, for example, rapid thermal chemical vapor deposition (RTCVD), low-energy plasma deposition (LEPD), ultra-high vacuum chemical vapor deposition (UHVCVD), atmospheric pressure chemical vapor deposition (APCVD), liquid-phase epitaxy (LPE), molecular beam epitaxy (MBE) and metal-organic chemical vapor deposition (MOCVD). The temperature for an epitaxial growth process can range from, for example, 550° C. to 900° C., but is not necessarily limited thereto, and can be conducted at higher or lower temperatures as needed.

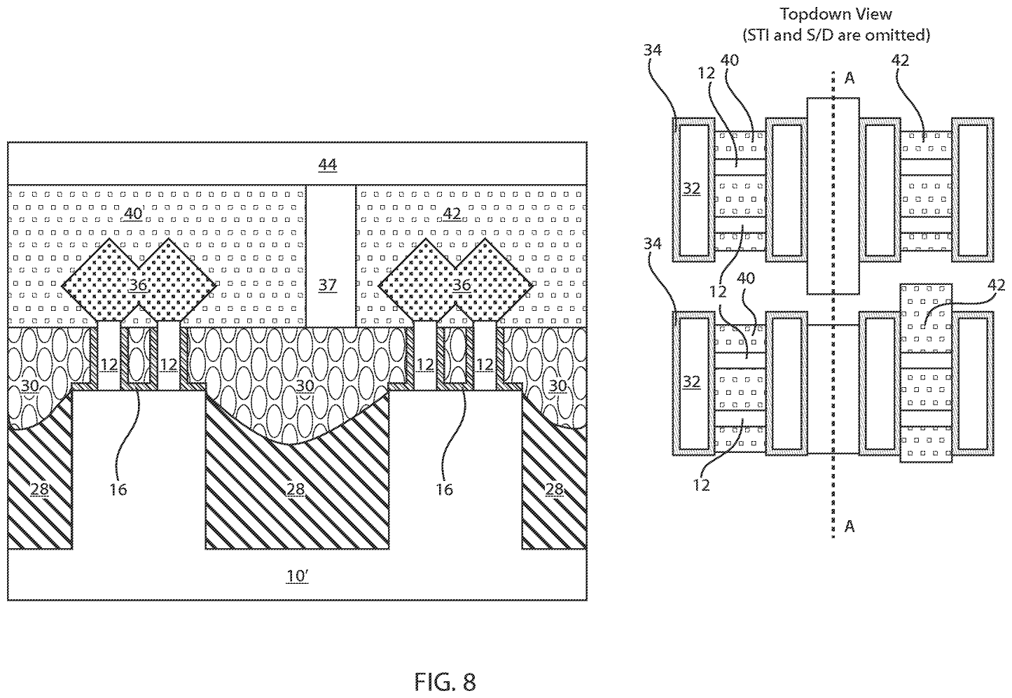

FIG. 8 is a cross-sectional view of the semiconductor structure of FIG. 7 where middle-of-the line (MOL) and back-end-of-the-line (BEOL) formation is completed, in accordance with an embodiment of the present invention.

A first contact 40 is formed over one source/drain epi region 36 and a second contact 42 is formed over another source/drain epi region 36. The first contact 40 can be referred to as a contact to a power rail and the second contact 42 can be referred to as a contact to signal. BEOL formation 44 can take place over the first and second contacts 40, 42. It is noted that a dielectric layer 37 can be formed directly between the first contact 40 and the second contact 42 to separate the first contact 40 from the second contact 42.

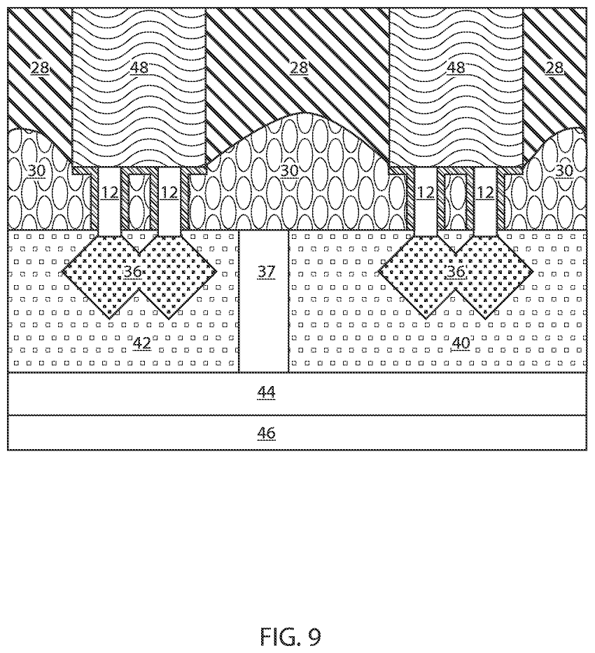

FIG. 9 is a cross-sectional view of the semiconductor structure of FIG. 8 where the wafer is flipped and mounted to a wafer carrier or another wafer to expose the epitaxial growth, in accordance with an embodiment of the present invention.

The semiconductor configuration of FIG. 8 is flipped such that the epitaxial growth 28 is exposed at a top portion thereof by removing the substrate down to the level of the sacrificial SiGe level. The semiconductor configuration of FIG. 8 or wafer is mounted to a wafer carrier 46, such as, e.g., an interposer or another wafer including other circuitry. The Si substrate backside can be designated as 48.

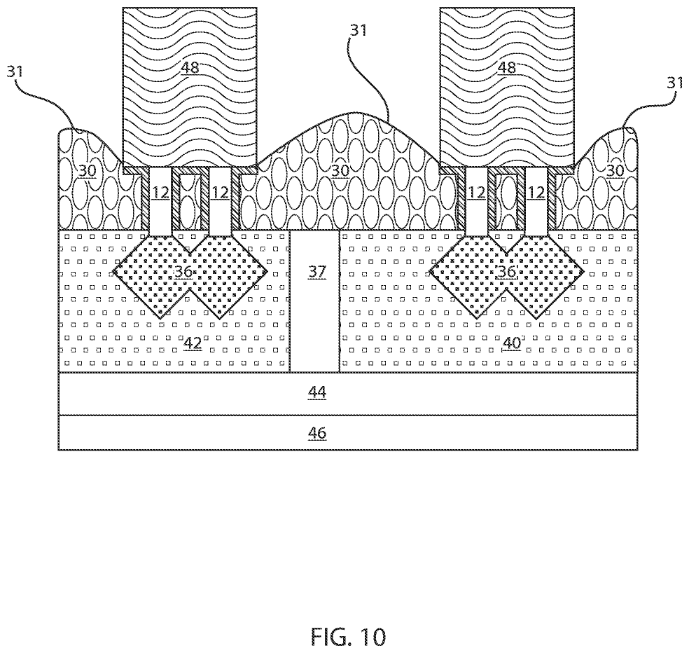

FIG. 10 is a cross-sectional view of the semiconductor structure of FIG. 9 where the epitaxial growth is selectively removed, in accordance with an embodiment of the present invention.

The epitaxial growth 28 is selectively removed to expose the STI regions 30. The convex surface 31 of the STI regions 30 is thus exposed. The removal of the epitaxial growth 28 further results in trenches 50 being formed. The removal of the epitaxial growth 28 can be performed by, e.g., using a vapor phase hydrochloric acid (HCl) dry etch or a wet etch process containing a mix of ammonia and hydrogen peroxide, or another suitable etching process.

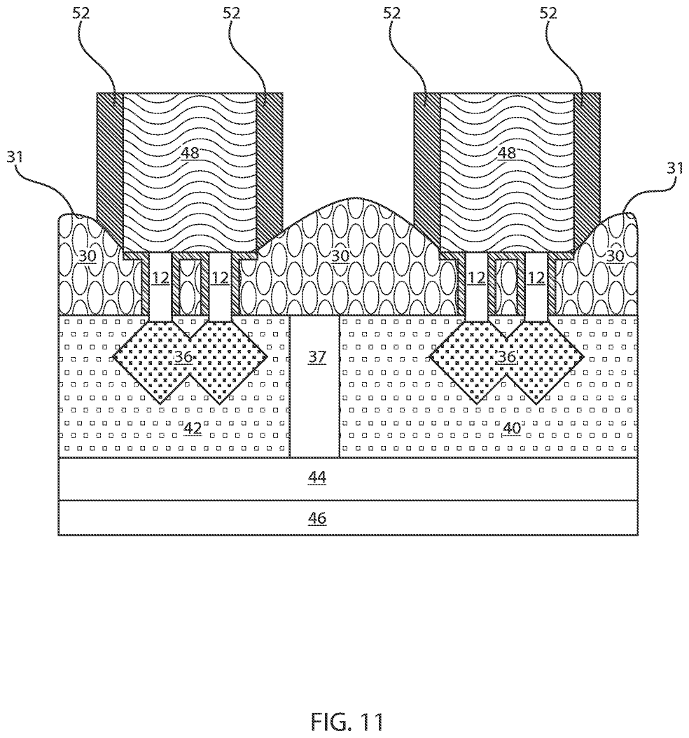

FIG. 11 is a cross-sectional view of the semiconductor structure of FIG. 10 where dielectric spacers are formed adjacent trench sidewalls, in accordance with an embodiment of the present invention.

Spacers 52 are formed adjacent the trench sidewalls by deposition followed by RIE. The spacers 52 isolate the buried power rail (BPR) from the rest of the substrate.

Spacers 52 can include any one or more of SiN, SiBN, SiCN and/or SiBCN films.

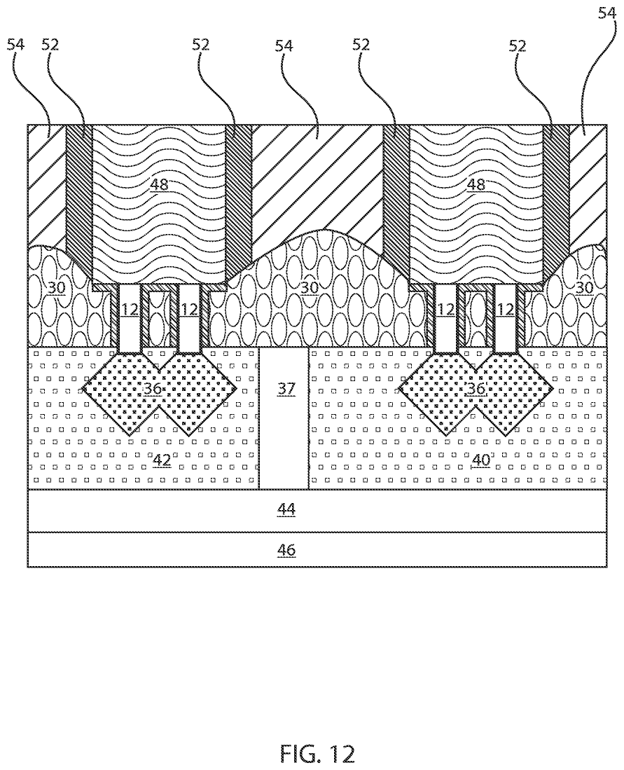

FIG. 12 is a cross-sectional view of the semiconductor structure of FIG. 11 where a low-k dielectric is deposited and planarized, in accordance with an embodiment of the present invention.

A low-k dielectric 54 is then deposited adjacent the spacers 52.

In some embodiments, “low-k dielectric” refers to an insulating material having a dielectric constant less than 7. In other embodiments, “low-k dielectric” refers to an insulating material having a dielectric constant less than that of silicon oxide, e.g., 3.9. Exemplary low-k dielectric materials include, but are not limited to, dielectric nitrides (e.g., SiN, SiBCN), dielectric oxynitrides (e.g., SiOCN, SiCO), carbon-doped silicon oxide, fluorine doped silicon oxide, or any combination thereof or the like.

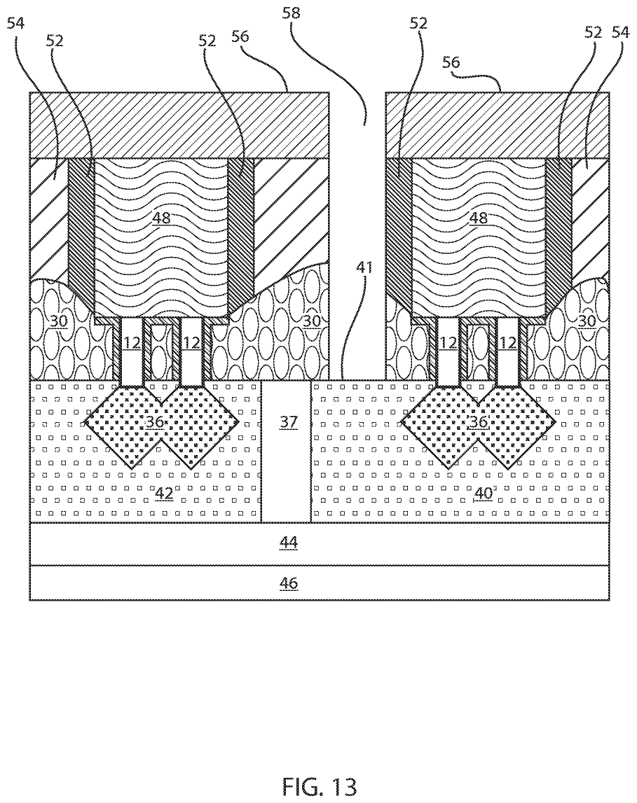

FIG. 13 is a cross-sectional view of the semiconductor structure of FIG. 12 where a mask is applied and an opening is created to the power rail contact 40, in accordance with an embodiment of the present invention.

A mask 56 is applied and a directional RIE is performed to create an opening 58 extending to a top surface 41 of the first contact 40 or MOL contact 40, that is, the contact to the power rail. After the formation of the opening 58, exposed dielectric 54 around the opening 58 can be removed, e.g., by any suitable isotropic etch, stopping on the spacer 52.

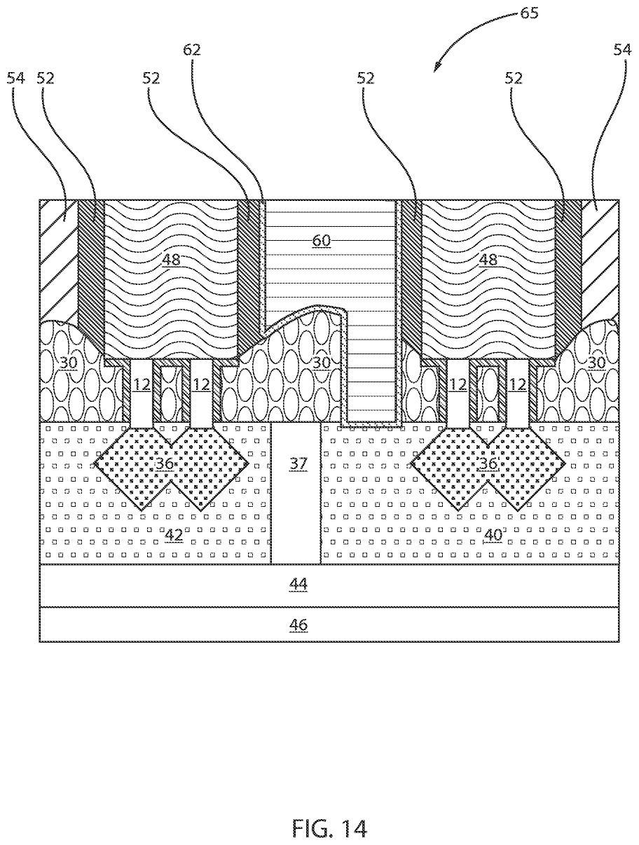

FIG. 14 is a cross-sectional view of the semiconductor structure of FIG. 13 where the mask is removed and a metal fill takes place to create the buried power rail, in accordance with an embodiment of the present invention.

The mask 56 is removed, a liner 62 is deposited, and a metal fill 60 takes place. The metal fill 60 is the buried power rail. The metal fill can be planarized.

The planarizing process can include chemical mechanical polishing (CMP) followed by an etch process. Therefore, the planarization process can be provided by CMP. Other planarization processes can include grinding and polishing.

As noted, the metal fill 60 represents the BPR. The BPR 60 can have an irregular shape. For example, the BPR 60 has a wide upper portion and a narrow lower portion. The narrow lower portion directly contacts the MOL contact 40. The irregular shape is a shape that is not even or balanced in shape or arrangement. The irregular shape of the BPR can be characterized as asymmetrical or non-uniform or uneven or lopsided or jagged at one or more locations. Note that the profile of the BPR is largely determined by the profile of the sacrificial SiGe. Thanks to the selective nature of the epitaxy process, the top corners of the sacrificial SiGe are substantially at the same level as the bottom of the dielectric liner 16 (and the bottom of the fins). As a result, after the sacrificial SiGe is replaced by the BPR, the corner of BPR abutting the spacer 52 is substantially aligned to the bottom of fin (offset by the spacer 52).

The BPR 60 is located at a first level, where the BPR 60 includes a first conductive material, and where the BPR 60 is in contact with a second level including the first contact 40, where a first portion of the BPR 60 closest to the first contact has a first thickness, where a second portion of the BPR 60 has a second thickness, and where the first thickness is less than the second thickness.

The first portion (lower portion) of the BPR 60 having a first thickness is confined between STI regions 30, whereas the second portion (upper portion) of the BPR 60 having a second thickness is confined between spacers 52.

Moreover, the BPR 60 is vertically offset from the plurality of fins 12.

The structure including the BPR 60 can be designated as 65.

The liner 62 can be, e.g., a titanium/titanium nitride (Ti/TiN) layer or metal liner. The liner 62 can be titanium nitride (TiN), tantalum (Ta), tantalum nitride (TaN), hafnium nitride (HfN), niobium nitride (NbN), tungsten nitride (WN), tungsten carbon nitride (WCN), or combinations thereof. In various embodiments, the barrier layer can be deposited in the trench(es) by ALD, CVD, PVD, MOCVD, PECVD, or combinations thereof.

The metal liner 62 is located between the conductive material and the first contact 40. Stated differently, the metal liner 62 provides an interface between the BPR 60 and the MOL power rail contact 40. The metal liner 62 directly contacts sidewalls of the upper portion of the BPR 60 and sidewalls of the lower portion of the BPR 60. The metal liner 62 directly contacts the sidewalls of the spacers 52 and further directly contacts portions of STI regions 30. There is no metal liner between the first portion of the BPR and the second portion of the BPR.

Advantageously, the resistance of BPR can be reduced by not having a metal liner within BPR. The metal fill or BPR 60 can be formed from, including but not limited to, tungsten (W), aluminum (Al), copper (Cu), cobalt (Co), nickel (Ni), titanium (Ti), ruthenium (Ru), molybdenum (Mo), or any other suitable conductive material. The metal fill 60 can further include a barrier layer. In various embodiments, the metal fill 60 can be formed by ALD, CVD, PVD, and/or plating. A planarization process such as chemical mechanical polish (CMP) can be performed after deposition to planarize the top surface of the BPR.

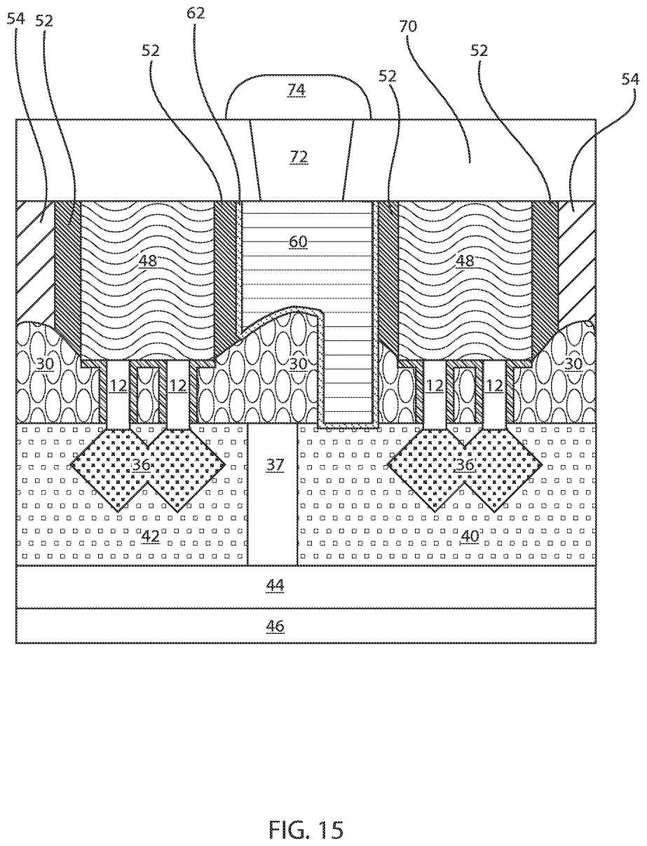

FIG. 15 is a cross-sectional view of the semiconductor structure of FIG. 14 where a power supply is formed on the backside of the wafer, in accordance with an embodiment of the present invention.

In another embodiment, a power supply 74 can be formed on the backside of the wafer. For example, a dielectric 70 can be deposited and a conductive via 72 can be formed through the dielectric 70. The power supply 74 can be incorporated adjacent the conductive via 72.

Consequently, the exemplary embodiments of the present invention provide a method and structure for advantageously forming a BPR by using self-aligned SiGe epitaxy as a sacrificial placeholder for the BPR. The exemplary embodiments advantageously eliminate the metal contamination issue as SiGe is fully compatible with FEOL processes and precise controlling of the BPR height is achievable as SiGe epitaxy is selective and self-aligned. Advantageously, thanks to the selective epitaxy, the sacrificial SiGe grows only on exposed semiconductor surfaces and not on the dielectric liner. Structurally, the top corners of the sacrificial SiGe are substantially at the same level as the bottom of the dielectric liner (and the bottom of the fins). Later on when the BPR is formed in place of the sacrificial SiGe, the BPR follows the profile of the sacrificial SiGe and advantageously allows the precise placement of BPR relative to fin bottom.

In conclusion, the exemplary embodiments advantageously form fins over a substrate, deposit a first conformal dielectric (e.g., SiN), deposit a second conformal dielectric (e.g., oxide) to pinch off fins with tight pitch while leaving spacing between fin arrays, recess the substrate to form trenches for the buried power rail (BPR), epitaxially grow sacrificial SiGe in BPR trenches, form STI, form FEOL, MOL and BEOL structures, flip the wafer and mount the wafer to a wafer carrier, selectively remove the sacrificial SiGe in BPR trenches, form sidewall spacers on substrate backside, pattern the MOL power rail contact, and form metallization of BPR and the MOL power rail contact. As a result, improved BPR with full compatibility with FEOL processes and precise control of BPR depth uniformity can advantageously be achieved. The structure includes a BPR with a wide portion and a narrow portion, where the BPR connects to a contact (CA), and a metallic liner along the sidewalls of the BPR such that it acts as an interface between the BPR and the CA contact. The method broadly includes epitaxially growing a sacrificial SiGe in the BPR trench as a placeholder in early stage device fabrication, such that after device formation, the SiGe can be advantageously removed to form the BPR.

Regarding FIGS. 1-15, deposition is any process that grows, coats, or otherwise transfers a material onto the wafer. Available technologies include, but are not limited to, thermal oxidation, physical vapor deposition (PVD), chemical vapor deposition (CVD), electrochemical deposition (ECD), molecular beam epitaxy (MBE) and more recently, atomic layer deposition (ALD) among others. As used herein, “depositing” can include any now known or later developed techniques appropriate for the material to be deposited including but not limited to, for example: chemical vapor deposition (CVD), low-pressure CVD (LPCVD), plasma-enhanced CVD (PECVD), semi-atmosphere CVD (SACVD) and high density plasma CVD (HDPCVD), rapid thermal CVD (RTCVD), ultra-high vacuum CVD (UHVCVD), limited reaction processing CVD (LRPCVD), metal-organic CVD (MOCVD), sputtering deposition, ion beam deposition, electron beam deposition, laser assisted deposition, thermal oxidation, thermal nitridation, spin-on methods, physical vapor deposition (PVD), atomic layer deposition (ALD), chemical oxidation, molecular beam epitaxy (MBE), plating, evaporation.

The term “processing” as used herein includes deposition of material or photoresist, patterning, exposure, development, etching, cleaning, stripping, implanting, doping, stressing, layering, and/or removal of the material or photoresist as needed in forming a described structure.

Removal is any process that removes material from the wafer: examples include etch processes (either wet or dry), and chemical-mechanical planarization (CMP), etc.

Patterning is the shaping or altering of deposited materials, and is generally referred to as lithography. For example, in conventional lithography, the wafer is coated with a chemical called a photoresist; then, a machine called a stepper focuses, aligns, and moves a mask, exposing select portions of the wafer below to short wavelength light; the exposed regions are washed away by a developer solution. After etching or other processing, the remaining photoresist is removed. Patterning also includes electron-beam lithography.

Modification of electrical properties can include doping, such as doping transistor sources and drains, generally by diffusion and/or by ion implantation. These doping processes are followed by furnace annealing or by rapid thermal annealing (RTA). Annealing serves to activate the implanted dopants.

It is to be understood that the present invention will be described in terms of a given illustrative architecture; however, other architectures, structures, substrate materials and process features and steps/blocks can be varied within the scope of the present invention.

It will also be understood that when an element such as a layer, region or substrate is referred to as being “on” or “over” another element, it can be directly on the other element or intervening elements can also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements can be present. In contrast, when an element is referred to as being “directly connected” or “directly coupled” to another element, there are no intervening elements present.

The present embodiments can include a design for an integrated circuit chip, which can be created in a graphical computer programming language, and stored in a computer storage medium (such as a disk, tape, physical hard drive, or virtual hard drive such as in a storage access network). If the designer does not fabricate chips or the photolithographic masks used to fabricate chips, the designer can transmit the resulting design by physical mechanisms (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which include multiple copies of the chip design in question that are to be formed on a wafer. The photolithographic masks are utilized to define areas of the wafer to be etched or otherwise processed.

Methods as described herein can be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip is mounted in a single chip package (such as a plastic carrier, with leads that are affixed to a motherboard or other higher level carrier) or in a multichip package (such as a ceramic carrier that has either or both surface interconnections or buried interconnections). In any case, the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

It should also be understood that material compounds will be described in terms of listed elements, e.g., SiGe. These compounds include different proportions of the elements within the compound, e.g., SiGe includes SiₓGe₁₋ₓ where x is less than or equal to 1, etc. In addition, other elements can be included in the compound and still function in accordance with the present embodiments. The compounds with additional elements will be referred to herein as alloys. Reference in the specification to “one embodiment” or “an embodiment” of the present invention, as well as other variations thereof, means that a particular feature, structure, characteristic, and so forth described in connection with the embodiment is included in at least one embodiment of the present invention. Thus, the appearances of the phrase “in one embodiment” or “in an embodiment”, as well any other variations, appearing in various places throughout the specification are not necessarily all referring to the same embodiment.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This can be extended, as readily apparent by one of ordinary skill in this and related arts, for as many items listed.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

Spatially relative terms, such as “beneath,” “below,” “lower,” “above,” “upper,” and the like, can be used herein for ease of description to describe one element's or feature's relationship to another element(s) or feature(s) as illustrated in the FIGS. It will be understood that the spatially relative terms are intended to encompass different orientations of the device in use or operation in addition to the orientation depicted in the FIGS. For example, if the device in the FIGS. is turned over, elements described as “below” or “beneath” other elements or features would then be oriented “above” the other elements or features. Thus, the term “below” can encompass both an orientation of above and below. The device can be otherwise oriented (rotated 90 degrees or at other orientations), and the spatially relative descriptors used herein can be interpreted accordingly. In addition, it will also be understood that when a layer is referred to as being “between” two layers, it can be the only layer between the two layers, or one or more intervening layers can also be present.

It will be understood that, although the terms first, second, etc. can be used herein to describe various elements, these elements should not be limited by these terms. These terms are only used to distinguish one element from another element. Thus, a first element discussed below could be termed a second element without departing from the scope of the present concept.

Having described preferred embodiments of a method for forming a semiconductor device with a buried power rail (which are intended to be illustrative and not limiting), it is noted that modifications and variations can be made by persons skilled in the art in light of the above teachings. It is therefore to be understood that changes may be made in the particular embodiments described which are within the scope of the invention as outlined by the appended claims. Having thus described aspects of the invention, with the details and particularity required by the patent laws, what is claimed and desired protected by Letters Patent is set forth in the appended claims.

1. A semiconductor structure comprising:
a field effect transistor (FET) having a source/drain;
a contact in contact with the source/drain; and
a buried power rail including a conductive material, wherein the buried power rail is in contact with the contact, wherein a first portion of the buried power rail closest to the contact has a first thickness, and wherein a second portion of the buried power rail has a second thickness such that the first thickness is less than the second thickness.

2. The semiconductor structure of claim 1, wherein the buried power rail further includes a metal liner.

3. The semiconductor structure of claim 2, wherein the metal liner is located between the conductive material and the contact.

4. The semiconductor structure of claim 1, wherein the FET is vertically offset from the buried power rail.

5. The semiconductor structure of claim 1, wherein the buried power rail has an irregular shape.

6. The semiconductor structure of claim 1, wherein the first portion of the buried power rail having a first thickness is confined between shallow trench isolation (STI) regions.

7. The semiconductor structure of claim 1, wherein the second portion of the buried power rail having a second thickness is confined between spacers.

8. A method for forming a buried power rail, the method comprising:
forming a plurality of fins over a substrate;
depositing a first conformal dielectric over the plurality of fins;
depositing a second conformal dielectric over the first conformal dielectric to pinch off fins of the plurality of fins with a tight pitch while leaving spacing between fin arrays;
recessing the substrate to form trenches for the buried power rail (BPR);
epitaxially growing a sacrificial material in the trenches;
forming shallow trench isolation (STI) regions over the sacrificial material;
forming front-end-of-the-line (FEOL), middle-of-the-line (MOL), and back-end-of-the-line (BEOL) structures to define a wafer structure having at least a MOL power rail contact;
flipping the wafer structure;
mounting the wafer structure to a wafer carrier;
selectively removing the sacrificial material;
forming sidewall spacers;
patterning the MOL power rail contact; and
forming metallization representing the BPR to the MOL power rail contact.

9. The method of claim 8, wherein the BPR has an irregular shape.

10. The method of claim 8, wherein the BPR has a first portion having a first thickness and a second portion having a second thickness, the first thickness being less than the second thickness.

11. The method of claim 10, wherein where the first portion of the BPR having the first thickness directly contacts the MOL power rail contact.

12. The method of claim 8, wherein the sacrificial material is silicon germanium (SiGe).

13. The method of claim 8, wherein sidewalls of the BPR directly contact a metallic liner.

14. The method of claim 13, wherein the metallic liner provides an interface between the BPR and the MOL power rail contact.

15. The method of claim 8, wherein the plurality of fins are vertically offset from the BPR.

16. A method for forming a buried power rail (BPR), the method comprising:
forming a plurality of fins over a substrate;
epitaxially growing sacrificial silicon germanium (SiGe) within the substrate;
forming front-end-of-the-line (FEOL), middle-of-the-line (MOL), and back-end-of-the-line (BEOL) structures to define a wafer structure having at least a MOL power rail contact;
flipping the wafer structure;
removing the sacrificial SiGe to form trenches; and
filling at least one of the trenches with a conductive material representing the BPR to the MOL power rail contact.

17. The method of claim 16, wherein the BPR has a first portion having a first thickness and a second portion having a second thickness, the first thickness being less than the second thickness.

18. The method of claim 17, wherein where the first portion of the BPR having the first thickness directly contacts the MOL power rail contact.

19. The method of claim 16, wherein sidewalls of the BPR directly contact a metallic liner.

20. The method of claim 19, wherein the metallic liner provides an interface between the BPR and the MOL power rail contact.
